(19) United States
(12) Patent Application Publication
(10) Pub. No.: US 2025/0133723 A1
(43) Pub. Date: Apr. 24, 2025

(54) STACK TYPE SEMICONDUCTOR MEMORY DEVICE

(71) Applicant: SK hynix Inc., Icheon-si (KR)

(72) Inventors: Myung Hee NA, Icheon-si (KR); Hye Jung CHOI, Icheon-si (KR); Jae Il KANG, Icheon-si (KR); Joong Sik KIM, Icheon-si (KR); Do Young JANG, Icheon-si (KR)

(21) Appl. No.: 18/442,073

(22) Filed: Feb. 14, 2024

(30) Foreign Application Priority Data
Oct. 23, 2023 (KR) 10-2023-0142100

(51) Int. Cl. H10B 12/00; H01L 23/00

(52) U.S. Cl. CPC H10B 12/33; H01L 24/08; H01L 24/80; H01L 2224/08145; H01L 2224/80895; H01L 2224/80896; H01L 2924/1436

(57) ABSTRACT

A stack type semiconductor memory device may include a first structure and a second structure. The first structure may include a first substrate, a capacitor array and a first bonding layer. The first substrate may have an upper surface and a lower surface. The capacitor array may include a plurality of capacitors integrated on the upper surface of the first substrate. The first bonding layer may be formed on the capacitor array. The second structure may include a second substrate, an access array and a second bonding layer. The second substrate may have an upper surface and a lower surface. The access array may include a plurality of access transistors integrated on the upper surface of the second substrate. The second bonding layer may be formed on the lower surface of the second substrate. The second bonding layer may be hybrid-bonded to the first bonding layer.

### CROSS-REFERENCES TO RELATED APPLICATION

The present application claims priority under 35 U.S.C. § 119 (a) to Korean patent application number 10-2023-0142100, filed on Oct. 23, 2023, in the Korean Intellectual Property Office, which is incorporated herein by reference in its entirety.

### BACKGROUND

### 1. Technical Field

Various embodiments generally relate to a semiconductor integrated circuit device, more particularly, to a stack type semiconductor memory device.

### 2. Related Art

Increasing the degree of integration of a semiconductor device can increase performance and can also lower costs of the semiconductor device for customers.

The integration degree of the semiconductor device is a factor for determining a price of an electronic part, where the integration degree of a two-dimensional or a planar semiconductor device can determine the pricing of an electronic part in accordance with an occupying area of a unit memory cell.

Particularly, because a fine pattern to increase the degree of integration may require an expensive exposure equipment or an exposure apparatus having a high resolution, there may exist an economic and physical limit of the increasing of the degree of integration in the two-dimensional semiconductor device.

To solve two-dimensional semiconductor device limitations and to increase and achieve a higher degree of integration of the semiconductor device, the memory cells can be stacked in three-dimension (3D) or a technology for stacking a memory cell array and a peripheral circuit is disclosed.

The stack type semiconductor device may include layers having elements formed by various processes so that maintenance of electrical properties between the elements may determine a performance of the stack type semiconductor device.

### SUMMARY

According to disclosed embodiments, there may be provided a stack type semiconductor memory device. stack type semiconductor memory device may include a first structure and a second structure. The first structure may include a first substrate, a capacitor array and a first bonding layer. The first substrate may have an upper surface and a lower surface. The capacitor array may include a plurality of capacitors integrated on the upper surface of the first substrate. The first bonding layer may be formed over the capacitor array. The second structure may include a second substrate, an access array and a second bonding layer. The second substrate may have an upper surface and a lower surface. The access array may include a plurality of access transistors integrated on the upper surface of the second substrate. The second bonding layer may be formed on the lower surface of the second substrate. The second bonding layer may be hybrid-bonded to the first bonding layer.

In the disclosed embodiments, the capacitor array and the access array may have a corresponding size.

In some embodiments, the second structure may further include a plurality of transistors and a peripheral circuit block. The transistors may be arranged on an outer perimeter of the access array. The peripheral circuit block may include a plurality of interconnections electrically connected to the transistors.

In other embodiments, the capacitor array may have a size corresponding to a size of the access array and the peripheral circuit block.

In the disclosed embodiments, the first structure may further include a plurality of micro capacitors arranged at a portion corresponding to the peripheral circuit block.

According to the disclosed embodiments, there may be provided a stack type semiconductor memory device. The stack type semiconductor memory device may include a first substrate and a second substrate. The first substrate may include a plurality of cell capacitors. The second substrate may include a plurality of word lines, a plurality of bit lines and an access transistor. The bit lines may intersect with the word lines. The access transistor may connect to intersected portions between the word lines and the bit lines. At least one of the first substrate and the second substrate may include a plurality of hybrid bonding pads electrically connected between the cell capacitors and the access transistors to form a memory cell array.

In disclosed embodiments, the second substrate may further include a plurality of transistors and a peripheral circuit block. The transistors may directly and indirectly connect to the word lines and the bit lines. The peripheral circuit block may include a plurality of interconnections. The peripheral circuit block may be on a surface of the second substrate where the access transistors, the word lines and the bit lines may be integrated with the peripheral circuit block.

In the disclosed embodiments, the first substrate may further include a plurality of micro capacitors arranged at a portion corresponding to the peripheral circuit block.

In disclosed embodiments, the stack type semiconductor memory device may further include a first bonding layer and a second bonding layer. The first bonding layer may form on the cell capacitors and the micro capacitors of the first substrate. The second bonding layer may form on the surface of the second substrate facing the first substrate. The second bonding layer may be boned to the first bonding layer. The first bonding layer and the second bonding layer may include a plurality of hybrid bonding pads.

According to disclosed embodiments, there is provided a method of manufacturing a stack type semiconductor memory device. In the method of manufacturing the stack type semiconductor memory device, a plurality of cell capacitors may form on one surface of a first substrate. A first bonding insulation layer may form on the capacitors. The first bonding insulation layer may include a plurality of first bonding pads electrically connected with the cell capacitors. A second bonding insulation layer can form on one surface of a second substrate. The second bonding insulation layer may include a plurality of second bonding pads. The first substrate may be hybrid-bonded to the second substrate to contact the first bonding pads with the second bonding pads. A plurality of access transistors may form at a region in the other surface of the second substrate where an access array can form.

According to disclosed embodiments, the capacitors formed by a high temperature process and circuit elements such as the transistor formed by a non-high temperature process may be integrated on the different substrates. Thus, preventing electrical changes of the circuit elements caused by the high temperature process.

Further, the circuit elements such as the transistors formed by the non-high temperature process may be formed after a middle temperature process operative substantially from 100° C. to 350° C. as a hybrid-bonding process and a high temperature process operative substantially from 400° C. to 700° C. for forming the capacitors. Thus, thermal burdens, which may change the electrical characteristics of the circuit elements can decrease. As a result, electrical characteristic of the stack type semiconductor device improves.

Furthermore, the circuit elements and the capacitors may form on the different substrates to increase integration degree of a memory device.

### BRIEF DESCRIPTION OF THE DRAWINGS

The above and another aspects, features, and advantages of the subject matter of the present disclosure will be more clearly understood from the following detailed description taken in conjunction with the accompanying drawings, in which:

FIG. 1 is a block diagram illustrating a stack type semiconductor memory device in accordance with example embodiments of the disclosure;

FIG. 2 is a perspective view illustrating a memory cell array of a stack type semiconductor memory device in accordance with example embodiments of the disclosure;

FIG. 3 is a perspective view illustrating a memory cell in accordance with example embodiments of the disclosure;

FIG. 4 is a cross-sectional view illustrating a stack type semiconductor memory device in accordance with example embodiments of the disclosure;

FIGS. 5 to 9 are cross-sectional views illustrating a method of manufacturing a memory cell array of a stack type semiconductor memory device in accordance with example embodiments of the disclosure;

FIG. 10 is a cross-sectional view illustrating a stack type semiconductor memory device in accordance with example embodiments of the disclosure;

FIG. 11 is a perspective view illustrating a stack type semiconductor memory device in accordance with example embodiments of the disclosure;

FIG. 12 is a perspective view illustrating a memory cell array of the stack type semiconductor memory device in FIG. 11;

FIG. 13 is a cross-sectional view illustrating the stack type semiconductor memory device in FIG. 11;

FIG. 14 is a perspective view illustrating a stack type semiconductor memory device in accordance with example embodiments of the disclosure; and

FIG. 15 is a cross-sectional view illustrating the stack type semiconductor memory device in FIG. 14.

### DETAILED DESCRIPTION

Various embodiments of the present disclosure are described in greater detail with reference to the accompanying drawings. The drawings are schematic illustrations of various embodiments (and intermediate structures). As such, variations from the configurations and shapes of the illustrations as a result, for example, of manufacturing techniques and/or tolerances, are to be expected. Thus, the described embodiments should not be construed as being limited to the configurations and shapes illustrated herein but may include deviations in configurations and shapes which do not depart from the spirit and scope of the present disclosure as defined in the appended claims.

The present disclosure described herein with reference to cross-section and/or plan illustrations of idealized embodiments of the present disclosure. However, embodiments of the present disclosure should not be construed as limiting the inventive concept. Although a few embodiments of the present disclosure will be shown and described, it will be appreciated by those of ordinary skill in the art that changes may be made in these embodiments without departing from the principles and spirit of the present disclosure.

As used herein, the term “configured” refers to a size, shape, material composition, orientation, and arrangement of one or more of at least one structure and at least one apparatus facilitating operation of one or more of the structures and the apparatus in a pre-determined way.

As used herein, the terms “vertical,” “longitudinal,” “horizontal,” and “lateral” are in reference to a plane of a structure and are not defined by earth's gravitational field. A “horizontal” or “lateral” direction is a direction that is substantially parallel to the plane of the structure, while a “vertical” or “longitudinal” direction is a direction that is substantially perpendicular to the plane of the structure. The plane of the structure is defined by a surface of the structure having a large area compared to other surfaces of the structure. With reference to the figures, a “horizontal” or “lateral” direction may be perpendicular to an indicated “Z” axis and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, features (e.g., regions, structures, devices) described as “neighboring” one another means and includes features of the disclosed identity (or identities) that are located proximate (e.g., closest to) one another. Additional features (e.g., additional regions, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located vertically proximate (e.g., vertically closest to) one another. Moreover, features described as “horizontally neighboring” one another means and includes features of the disclosed identity (or identities) that are located horizontally proximate (e.g., horizontally closest to) one another.

As used herein, spatially relative terms, such as “beneath,” “below,” “bottom,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” may encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the singular forms “a,” “an,” and “the” are intended to include the plural forms as well, unless the context clearly indicates otherwise.

As used herein, the phrase “coupled to” and “connected to” refer to structures operatively connected with each other, such as electrically connected through a direct Ohmic connection or through an indirect connection (e.g., by way of another structure).

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

In example embodiments of the disclosure, devices formed by a high temperature process and devices formed by a low temperature process may couple to different substrates. Further, to reduce the thermal burden of the devices formed by the low temperature process, devices formed by the low temperature process may be integrated after bonding the substrates to each other.

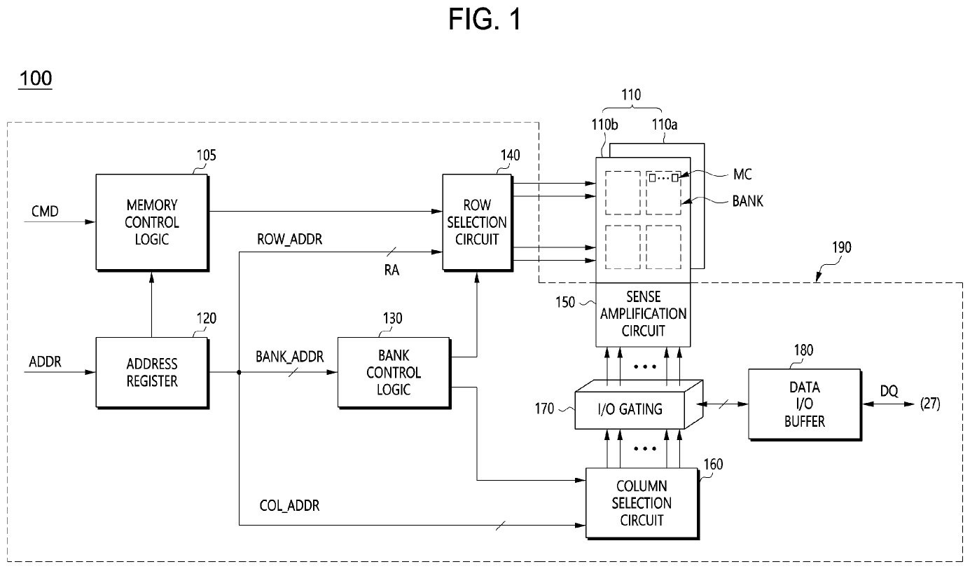

FIG. 1 is a block diagram illustrating a stack type semiconductor memory device in accordance with an embodiment of the disclosure.

Referring to FIG. 1, a stack type semiconductor memory device 100 of an embodiment of the disclosure may include a memory cell array 110 and a peripheral circuit block 190.

The memory cell array 110 may include a plurality of memory cells MC. The memory cell array 110 may further include at least two stack structures: first structure 110a and second structure 110b. In the embodiment of the disclosure, the memory cell array 110 may include a plurality of word lines and a plurality of bit lines intersected with each other. The memory cells MC may be connected to intersected portions between the word lines and the bit lines. The memory cells MC may be grouped and controlled into a bank unit. Further, the memory cells MC in the bank may be grouped and controlled into a mat unit. For example, the memory cell MC may include a dynamic random access memory (DRAM) cell. In an embodiment of the disclosure, the DRAM cell may include a selection transistor and a capacitor. The memory cell array 110 may further comprise the DRAM cell, a memory interface 27 to communicate based on any one of a double date rate (DDR), a low power double data rate (LPDDR), a graphics double data rate (GDDR), a wide I/O, a high bandwidth memory (HBM), and a hybrid memory cube (HMC), etc.

The memory cell array 110 may be illustrated in more detail below.

The peripheral circuit block 190 may include a memory control logic 105, an address register 120, a bank control logic 130, a row selection circuit 140, a column selection circuit 160, a sense amplification circuit 150, an input/output gating circuit 170 and a data input/output buffer 180.

The row selection circuit 140 may select and control the word lines in the memory cell array 110. The column selection circuit 160 may select and control the bit lines in the memory cell array 110. The sense amplification circuit 150 may include a plurality of sense amplifiers connected to the bit lines of the memory cell array 110.

The stack type semiconductor memory device 100 may receive a clock signal, a command CMD and address information ADDR based on the clock signal from an external device such as a memory controller.

The address register 120 may receive the address information ADDR from the memory controller to generate an internal address. The internal address may include a bank address BANK_ADDR, a row address ROW_ADDR and a column address COL_ADDR.

The bank control logic 130 may generate a bank control signal in response to the bank address BANK_ADDR. The bank control signal may be inputted into the row selection circuit 140 and the column selection circuit 160.

The row selection circuit 140 may receive the bank control signal and the row address ROW_ADDR to activate a selected row or a selected word line of a selected bank. The column selection circuit 160 may receive the bank control signal and the column address COL_ADDR to activate a selected column or a selected bit line of a selected bank. The column selection circuit 160 may activate the sense amplifier connected to the selected bank and the selected column or bit line through the input/output gating circuit 170.

The input/output gating circuit 170 may include at least one read data latch and at least one write driver. The read data latch may store data outputted from an input data mask logic and the memory cell array 110 together with circuits configured to gate input/output data. The write drive may register the data into the memory cell array 110.

In an embodiment of the disclosure, the sense amplification circuit 150 may sense data DQ read from a selected memory cell MC of a selected bank. The data DQ may be stored in the read data latch of the input/output gating circuit 170. The data DQ in the read data latch may be provided to the memory controller through the data input/output buffer 180.

The data DQ written in a selected memory cell of a selected bank may be provided to the data input/output buffer 180 from the memory controller. The data DQ in the data input/output buffer 180 may be stored in the selected memory cell of the selected bank through the write driver.

The memory control logic 105 may control operations of the stack type semiconductor memory device 100. The memory control logic 105 may generate control signals for performing an active operation of the stack type semiconductor memory device 100 such as a write operation or a read operation.

The peripheral circuit block 190 may include various circuits as well as the above-mentioned circuits.

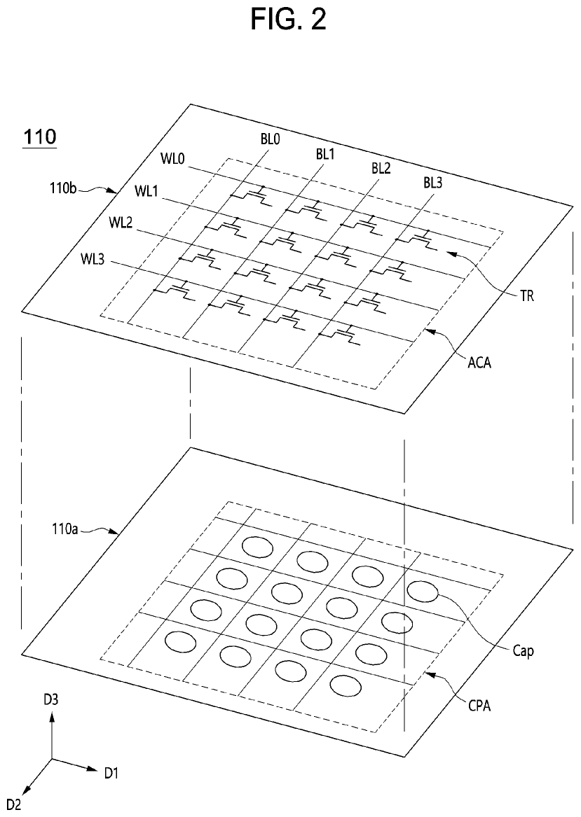

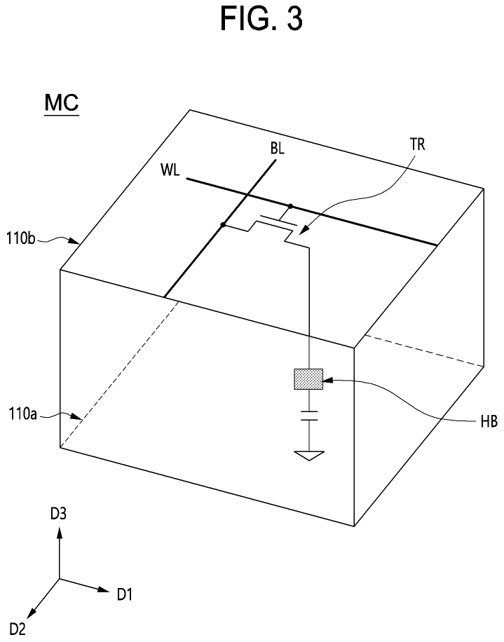

FIG. 2 is a perspective view illustrating a memory cell array of a stack type semiconductor memory device in accordance with an embodiment of the disclosure and FIG. 3 is a perspective view illustrating a memory cell in accordance with an embodiment of the disclosure.

Referring to FIGS. 1 to 3, a memory cell array 110 of an embodiment of the disclosure may include a first structure 110a and a second structure 110b sequentially stacked. The first structure 110a and the second structure 110b may bond to each other. The first structure 110a and the second structure 110b can comprise a wafer, a substrate, a chip, a part of a wafer with at least one chip, etc., The first structure 110a and the second structure 110b may correspond to a substrate resultant for integration of elements.

The first structure 110a may include a capacitor array CPA. The capacitor array CPA may include an arrangement of a plurality of capacitors Cap in a regular rule.

The second structure 110b may be stacked and bonded on the first structure 110a. An access array ACA may be integrated on one surface of the second structure 110b that is not bonded to the first structure 110a.

The access array ACA may include a plurality of word lines WL0˜WL3 and a plurality of bit lines BL0˜BL3. The arrangement of word lines WL0˜WL3 may be in parallel to each other along a row direction D1. The arrangement of bit lines BL0˜BL3 may be in parallel to each other in a column direction D2. The row direction D1 may be substantially perpendicular to the column direction D2. A direction D3 may be a stack direction. In an embodiment of the disclosure, the word lines WL0˜WL3 and the bit lines BL0˜BL3 intersect with each other to define a plurality of memory cell array regions.

The access array ACA may include a plurality of access transistors TR. The access transistors TR may connect to the intersected portions between the word lines WL0˜LW3 and the bit lines BL0˜BL3. Each of the access transistors TR may be positioned at the memory cell regions. The access transistors TR may correspond to the capacitors Cap of the first structure 110a. Thus, a size of the access array ACA may correspond to a size of the capacitor array CPA. The access transistors TR may be activated in accordance with selections of the word lines and the bit lines connected to the access transistors TR.

The capacitors Cap and the access transistors TR may be electrically connected with each other through a hybrid-bonding portion HB provided to at least one of the first structure 110a and the second structure 110b. For example, the first structure 110a and the second structure 110b may include hybrid-bonding pads configured to electrically connect the capacitors Cap with the access transistors TR. Thus, the memory cell array 110 of an embodiment of the disclosure can be a combination of the first structure 110a and a part of the second structure 110b stacked in a three-dimensional (3D) way.

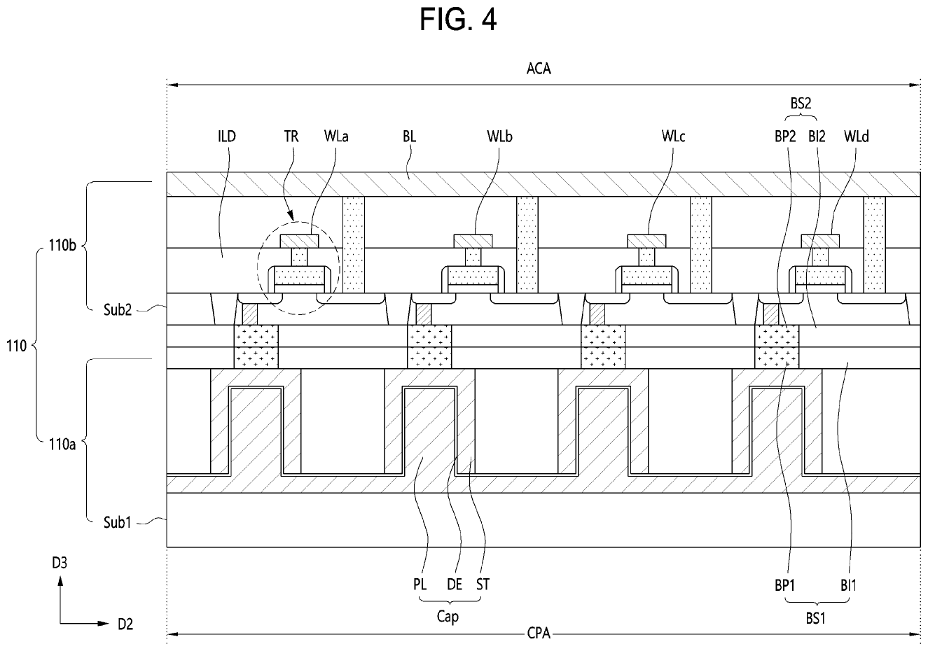

FIG. 4 is a cross-sectional view illustrating a stack type semiconductor memory device in accordance with an embodiment of the disclosure.

Referring to FIG. 4, a stack type semiconductor memory device 100 of an embodiment of the disclosure may include the first structure 110a and the second structure 110b hybrid-bonded to each other through a hybrid-bonding portion HB.

The first structure 110a may include a first substrate Sub1, a capacitor array CPA and a first bonding layer BS1.

The first substrate Sub1 may include a single crystalline silicon substrate, an epitaxial silicon substrate, a silicon germanium substrate, a polysilicon layer, a supporting layer with a semiconductor material, a silicon on insulator (SOI) substrate, etc., but not limited thereto. The first substrate Sub1 may have an upper surface and a lower surface.

The capacitor array CPA may be integrated on one surface of the first substrate Sub1, for example, the upper surface of the first substrate Sub1. The capacitor array CPA may include an arrangement of a plurality of capacitors Cap in a regular rule. For example, the capacitors Cap may include a plate electrode PL, a dielectric layer DE and a storage electrode ST. The storage electrodes ST of the capacitors Cap may be electrically isolated from each other. The plate electrodes PL of the capacitors Cap may be connected to each other. The dielectric layer DE may interpose between the plate electrode PL and the storage electrode ST. In an embodiment of the disclosure, the storage electrode ST may have a cylindrical shape, but not limited thereto. The regular rule may be substantially the same as the arrangement rule of the memory cell regions or the access transistors in FIGS. 2 and 3.

The first bonding layer BS1 may be formed on the first substrate Sub1 where the capacitor array CPA may be formed. The first bonding layer BS1 may include a plurality of first bonding pads BP1 and a first bonding insulation layer Bl1.

A part of the first bonding pads BP1 may electrically connect to the capacitors Cap. For example, the first bonding pads BP1 may be electrically connect to the storage electrode ST of the capacitors Cap. The first bonding insulation layer Bl1 may electrically insulate the first bonding pads BP1 from each other.

The second structure 110b may include a second substrate Sub2, an access array ACA and a second bonding layer BS2.

The second substrate Sub2 may include a silicon substrate, a single crystalline silicon substrate, an epitaxial silicon substrate, a silicon germanium substrate, etc., but not limited thereto. Further, the second substrate Sub2 may include an intrinsic semiconductor material or conductive impurities. The second substrate Sub2 may be substantially equal to, or different from the first substrate Sub1. The second substrate Sub2 may have an upper surface and a lower surface.

The access array ACA may be integrated on one surface of the second substrate Sub2, for example, the upper surface of the second substrate Sub2. The access array ACA may include a plurality of access transistors TR. Each of the access transistors TR may include a gate, a source, and a drain. The access transistors TR may have substantially the same structure. In an embodiment of the disclosure, a channel between the source and the drain of the access transistors TR may have a horizontal channel structure substantially parallel to the surface of the second substrate Sub2, but not limited thereto. For example, the channel may have a vertical channel structure substantially perpendicular to the surface of the second substrate Sub2, or a fin channel structure, etc.

The access array ACA may include a plurality of word lines WLa˜WLd and a plurality of bit lines BL. The word lines WLa˜WLd may be connected to the gates of the access transistors TR. The bit lines BL may be connected to the drains of the access transistors TR. As mentioned above, the word lines WLa˜WLd may be arranged in parallel to each other along the row direction D1. The bit lines BL may be arranged in parallel to each other along the column direction D2 perpendicular to the row direction D1.

In an embodiment of the disclosure, the gates of the access transistors TR in a same row may electrically connect to same word lines. The gates of the access transistors TR in different rows may electrically connect to different word lines.

Further, the drains of the access transistors TRa in the same column may electrically connect to same bit line. The drains of the access transistors TR in different columns may electrically connect to different bit lines. In FIG. 4, a part of the access transistors TR may connect to the same bit line BL and the different word lines WLa˜WLd.

The access array ACA may include a plurality of insulation interlayers ILD. The insulation interlayers ILD may be positioned between the upper surface of the second substrate Sub2 and the word lines WLa˜WLd and between the word lines WLa˜WLd and the bit lines BL. Thus, the word lines WLa˜WLd may be electrically isolated from the bit lines BL. Further, the access transistors TR may be electrically isolated from each other.

The second bonding layer BS2 may be formed on the other surface of the second substrate Sub2, for example, the lower surface of the second substrate Sub2 to face the second bonding layer BS2 and the first bonding layer BS2 each other. The second bonding layer BS2 may include a plurality of second bonding pads BP2 and a second bonding insulation layer BI2.

At least one of the second bonding pads BP2 may be electrically connected to the access transistor TR, for example, the source of the access transistor TR. The second bonding insulation layer BI2 may electrically insulate the second bonding pads BP2 from each other.

The second bonding layer BS2 may be hybrid-bonded to the first bonding layer BS1. For example, the second bonding insulation layer BI2 of the second bonding layer BS2 may be directly bonded to the first bonding insulation layer Bl1 of the first bonding layer BS1. Further, the second bonding pads BP2 of the second bonding layer BS2 may be directly bonded to the first bonding pads BP1 of the first bonding layer BS1.

By bonding the first bonding pads BP1 to the second bonding pads BP2, the access array ACA of the first structure 110a may be electrically combined with the capacitor array CPA of the second structure 110b to form the memory cell array 110 including the memory cells stacked in the 3D.

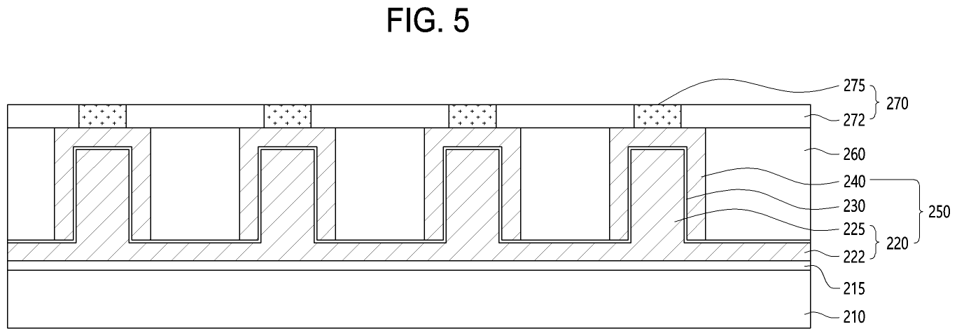

FIGS. 5 to 9 are cross-sectional views illustrating a method of manufacturing a memory cell array of a stack type semiconductor memory device in accordance with an embodiment of the disclosure.

Referring to FIG. 5, a first conductive layer may be formed on a first substrate 210. The first conductive layer may be patterned to form a common electrode layer 222.

For example, the first substrate 210 may be a bare semiconductor substrate. When the first substrate 210 may include a semiconductor material, an insulation layer 215 may be interposed between the first substrate 210 and the common electrode layer 222. The insulation layer 215 may electrically isolate the first substrate 210 from the common electrode layer 222. Alternatively, the first substrate 210 may include an insulation material. When the first substrate 210 may include the insulation material, the common electrode layer 222 may be directly formed on the first substrate 210 without the insulation layer 215.

A second conductive layer may be formed on the common electrode layer 222. The second conductive layer may be patterned to form a plurality of plate patterns 225.

For example, the second conductive layer may have a thickness thicker than the thickness of the first conductive layer. That is, the plate patterns 225 may have a thickness thicker than the thickness of the common electrode layer 222. Further, the common electrode layer 222 and the plate patterns 225 may include the same material or different materials. The plate patterns 225 may be formed in an arrangement to have a size and a gap in the above-mentioned rule. The plate patterns 225 may couple with the common electrode layer 222 to form a plate electrode 220.

A dielectric layer 230 may be formed on a surface of the plate electrode 220, for example, surfaces of the common electrode layer 222 and the plate patterns 225. In an embodiment of the disclosure, the dielectric layer 230 may have a uniform thickness. The dielectric layer 230 may include a metal oxide layer having a high dielectric constant. The metal oxide layer may include at least one of a hafnium oxide layer, a doped hafnium oxide layer, a hafnium zirconium oxide layer, a doped hafnium zirconium oxide layer, a tantalum oxide layer, a zirconium oxide layer, an aluminum oxide layer, and a titanium oxide layer. The dielectric layer 230 may crystallize by annealing at a high temperature of substantially 400° C. to 700° C.

A third conductive layer having a uniform thickness may be formed on the dielectric layer 230. The third conductive layer may be etched to form storage electrodes 240. The storage electrodes 240 may have a cylindrical shape configured to surround each of the plate patterns 225. Thus, a plurality of capacitors 250 may be formed on the first substrate 210.

In an embodiment of the disclosure, the third conductive layer for the storage electrode 240 may have a thickness thinner than a thickness of the plate patterns 225, but not limited thereto.

In an embodiment of the disclosure, at least one of the common electrode layer 222, the plate patterns 225 and the storage electrodes 240 may include iridium (Ir), ruthenium (Ru), platinum (Pt), or a novel metal having a high work function, etc.

In an embodiment of the disclosure, at least one of the common electrode layer 222, the plate patterns 225 and the storage electrodes 240 may include a metal nitride layer such as a titanium nitride layer.

In an embodiment of the disclosure, the crystallization process of the dielectric layer 230 may be performed after forming the dielectric layer 230 or after forming the storage electrode 240.

Although the dielectric layer 230 may be crystallized at the high temperature, the capacitors 250 or the plate electrode 220, which may not have a thermal burden by the high temperature, may be formed on the first substrate 210 so that an electrical problem caused by the crystallization process may not be generated.

An insulating interlayer 260 may be formed on the first substrate 210 with the capacitors 250. The insulating interlayer 260 may have a thickness for filling spaced between the capacitors 250. The insulating interlayer 260 may include at least one insulation layer. The insulation layer may include a planarizing material.

In an embodiment of the disclosure, the insulating interlayer 26t0 may be planarized by a chemical mechanical polishing (CMP) process. The insulating interlayer 260 may be planarized until the surface of the storage electrode 240 is exposed.

A first bonding insulation layer 272 may be formed on the insulating interlayer 260. The first bonding insulation layer 272 may include at least one insulation layer. The insulation layer may include a silicon oxide layer, a silicon nitride layer, etc.

Etching the first bonding insulation layer 272 may form first pad regions. The first pad regions may expose a part of the capacitors 250, for example, a part of the storage electrode 240.

A first pad metal layer may be formed on the first bonding insulation layer 272 to fill up the first pad regions. The first pad metal layer may include copper. The first pad metal layer may be planarized until the first bonding insulation layer 272 may be exposed to form first bonding pads 275 in the first pad regions. The first bonding pads 275 may be directly and indirectly connected to the storage electrode 240. Alternatively, although not illustrated in the drawings, at least one interconnection may be interposed between the storage electrode 240 and the first bonding pads 275.

A reference numeral 270 may indicate a first bonding layer including the first bonding insulation layer 272 and the first bonding pads 275. A reference numeral 200 may indicate a resultant of the first substrate 210 (hereinafter, referred to as a first structure) including the capacitors 250 and the first bonding layer 270 sequentially stacked.

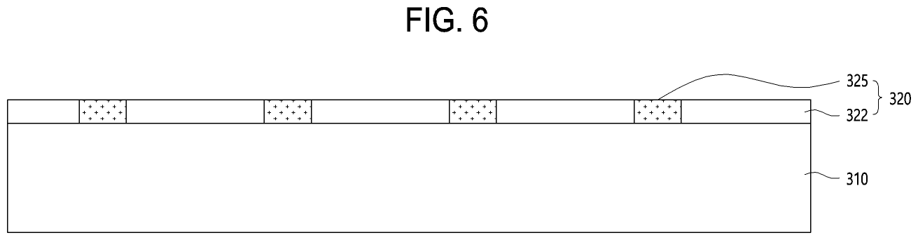

Referring to FIG. 6, a second substrate 310 may be prepared. The second substrate 310 may bond to the first structure 200. The second substrate 310 may include a bare semiconductor substrate. The second substrate 310 may have an upper surface and a lower surface.

A second bonding insulation layer 322 may be formed on any surface selected from the upper surface and the lower surface of the second substrate 310. The second bonding insulation layer 322 may include at least one insulation layer. The insulation layer may include a silicon oxide layer, a silicon nitride layer, etc. The second bonding insulation layer 322 may include a material and a structure, substantially the same as the structure and material of the first bonding insulation layer 272. Alternatively, the material and the structure of the second bonding insulation layer 322 may be different from the material and the structure of the first bonding insulation layer 272.

Etching the second bonding insulation layer 322 may form second pad regions. The second pad regions may be configured to expose selected portions of the second substrate 310. A pad metal layer may be formed on the second bonding insulation layer 322. The pad metal layer may have a thickness for filling the second pad regions. The pad metal layer may be planarized until a surface of the second bonding insulation layer 322 may be exposed to form second bonding pads 325 in the second pad regions. Thus, a second bonding layer 320 may be formed on the upper surface of the second substrate 310. The second bonding layer 320 may include the second bonding insulation layer 322 and the second bonding pads 325.

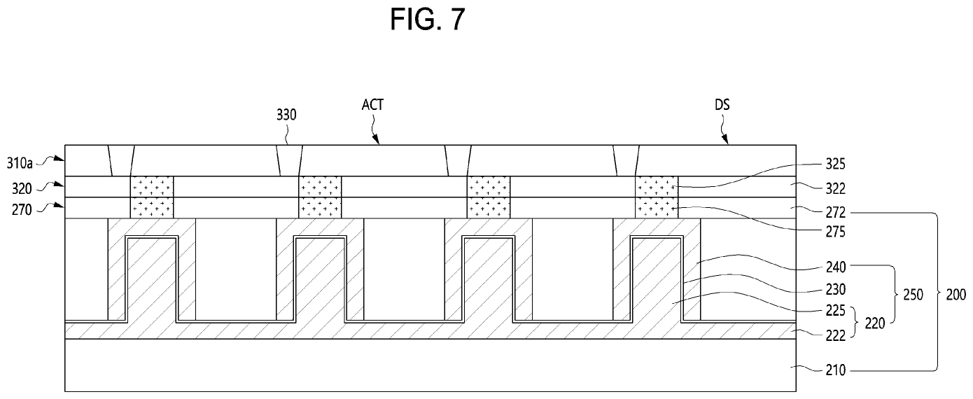

Referring to FIG. 7, the second substrate 310 may be stacked on the first structure 200 to face the first bonding layer 270 of the first structure 200 and the second bonding layer 320 of the second substrate 310 to each other.

In an embodiment of the disclosure, the first structure 200 and the second substrate 310 may be aligned with each other to correspond the first bonding pads 275 to the second bonding pads 325.

The first bonding layer 270 may be hybrid-bonded to the second bonding layer 320. Particularly, a backside of the second substrate 310 on the first structure 200 may be compressed to preliminarily bond the first bonding insulation layer 272 to the second bonding insulation layer 322. An annealing process may be performed at a temperature from substantially 100° C. to 350° C., in order to induce metal bonding by thermal expansions of the first bonding pads 275 and the second bonding pads 325.

In an embodiment of the disclosure, the first structure 200 may include capacitors 250 having a thermal endurance of substantially 400° C. to 700° C. In contrast, any element except for the second bonding layer 320 may not be formed on the second substrate 310. Thus, electrical characteristics of the first structure 200 and the second substrate 310 may not be changed by the annealing process for the metal bond.

When the second substrate 310 is bonded to the first structure 200, a non-selected surface of the second substrate 310 may be exposed. The non-selected surface of the second substrate 310 may be grinded to form a second substrate 310a having a thin thickness. In an embodiment of the disclosure, the thickness of the second substrate 310a may be thinner than the thickness of the first substrate 210. Hereinafter, the grinded non-selected surface of the second substrate 310a may be referred to as a device surface DS.

An isolation layer 330 may be formed in the second substrate 310a to define regions where memory cells may be formed, for example, active regions ACT. The isolation layer 330 may be formed by a shallow trench isolation (STI) process. A depth of the isolation layer 330 may be changed by a designer. First conductive type impurities may be implanted into the active region ACT to form a well region.

In an embodiment of the disclosure, the active region ACT may correspond to the capacitor 250 of the first structure 200.

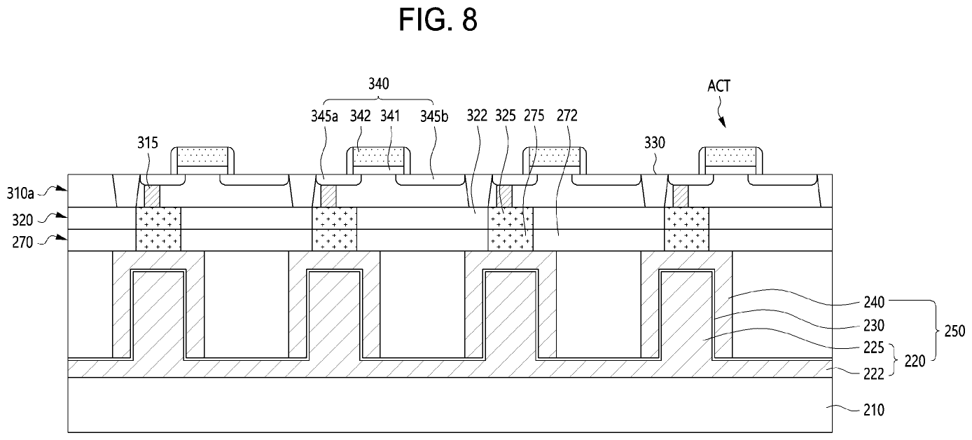

Referring to FIG. 8, a gate 342 may be formed on the active region ACT. A gate insulation layer 341 may be interposed between the gate 342 and the device surface DS of the second substrate 310a. Second conductive type impurities may be implanted into the active regions ACT at both sides of the gate 342 to form a source 345a and a drain 345b. Thus, an access transistor 340 may be integrated in each of the active regions ACT of the second substrate 310a.

For example, each of the sources 345a may correspond to each of the second bonding pads 325.

Further, before forming the access transistor 340, during forming the access transistor 340, or after forming the access transistor 340, an embedded electrode 315 may be formed in the second substrate 310a to connect the source 345a with the second bonding pad 325.

For example, the embedded electrode 315 may be formed in a through silicon via (TSV). The embedded electrode 315 may include multi-layered interconnections. Alternatively, the embedded electrode 315 may include an impurity region such as a deep well. In an embodiment of the disclosure, the embedded electrode 315 may couple with a bottom surface of the source 345a. Alternatively, the embedded electrode 315 may be formed through the source 345a. Further, the embedded electrode 315 may couple with a side surface of the source 345a.

The embedded electrode 315 may be electrically isolated from the second substrate 310a. Although not depicted in drawings, an insulation layer may be interposed between a sidewall of the embedded electrode 315 and the second substrate 310a.

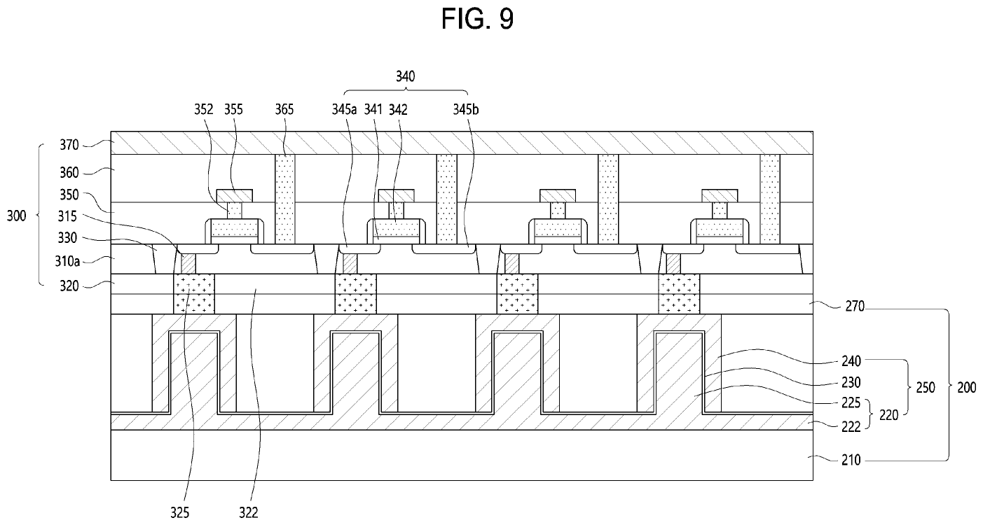

Referring to FIG. 9, a first insulating interlayer 350 may be formed on the device surface DS of the second substrate 310a with the access transistors 340. The first insulating interlayer 350 may include at least one insulation layer. Alternatively, the first insulating interlayer 350 may include at least one planarization layer.

The first insulating interlayer 350 may be etched until the upper surface of the gate 342 may be exposed to form a word line contact hole. The word line contact hole may be filled with a conductive material to form a word line contact 352. A metal layer may be formed on the first insulating interlayer 350. The metal layer may couple with the word line contact 352. The metal layer may be patterned to form a first wiring 355. The first wiring 355 may be a word line or a part of a word line.

A second insulating interlayer 360 may be formed on the first insulating interlayer 350. The second insulating interlayer 360 may include an insulation material substantially equal to or different from the insulation material of the first insulating interlayer 350. The second insulating interlayer 360 and the first insulating interlayer 350 may be etched until the drains 345b of the access transistors 340 may be exposed to form a bit line contact hole. The bit line contact hole may be filled with a conductive material to form a bit line contact 365. A metal layer may be formed on the second insulating interlayer 360. The metal layer may couple with the bit line contact 365. The metal layer may be patterned to form a second wiring 370. The second wiring 370 may be a bit line or a part of a bit line.

A reference numeral 300 may indicate a resultant of the second substrate 310a with the access transistors 340, the word line and the bit line, i.e., a second structure.

According to an embodiment of the disclosure, the capacitors formed by the high temperature process and the access transistors formed by the low temperature process may be integrated on the different substrates. Particularly, after forming the capacitor by the high temperature process, the access transistor may then be formed so that the thermal burden to the access transistor may be decreased.

Further, the access transistor may be integrated on the hybrid-bonded substrate so that the additional thermal burden in the hybrid-bonding process may also be decreased.

Furthermore, the access transistor and the capacitor may be formed on the different substrates so that the capacitor may have an increased capacitance by a secured area, or the memory cell may have an increased integration degree.

Moreover, the access transistor and the capacitor may be directly connected to the hybrid-bonding portion HB, for example, the bonding pad, not through the interconnections, so that a connection path may be reduced to decrease a signal delay.

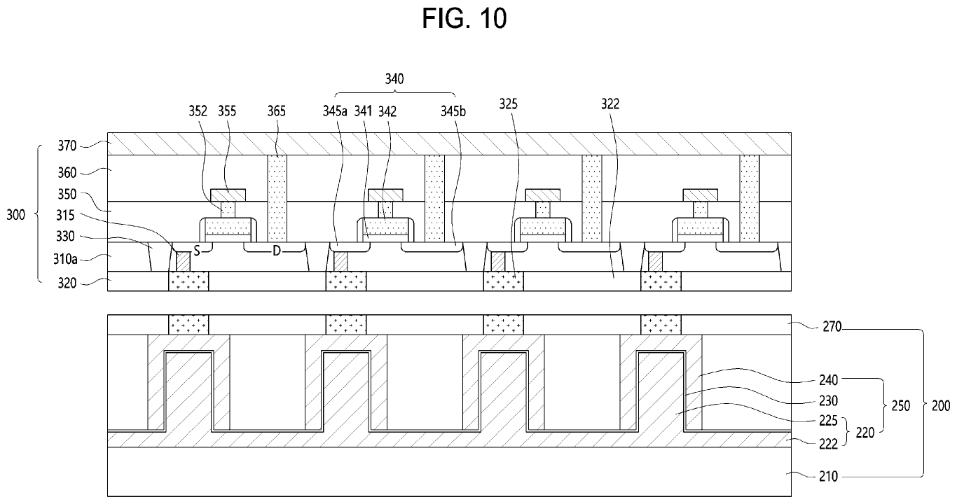

FIG. 10 is a cross-sectional view illustrating a stack type semiconductor memory device in accordance with an embodiment of the disclosure.

Referring to FIG. 10, the access transistors 340, the first wiring 355, second wiring 370 and the second bonding layer 320 may be individually formed on the second substrate 310a, which may not be bonded to the first structure 200, to form the second structure 300.

The first bonding layer 270 of the first structure 200 may be hybrid-bonded to the second bonding layer 320 of the second structure 300 to complete the stack type semiconductor memory device.

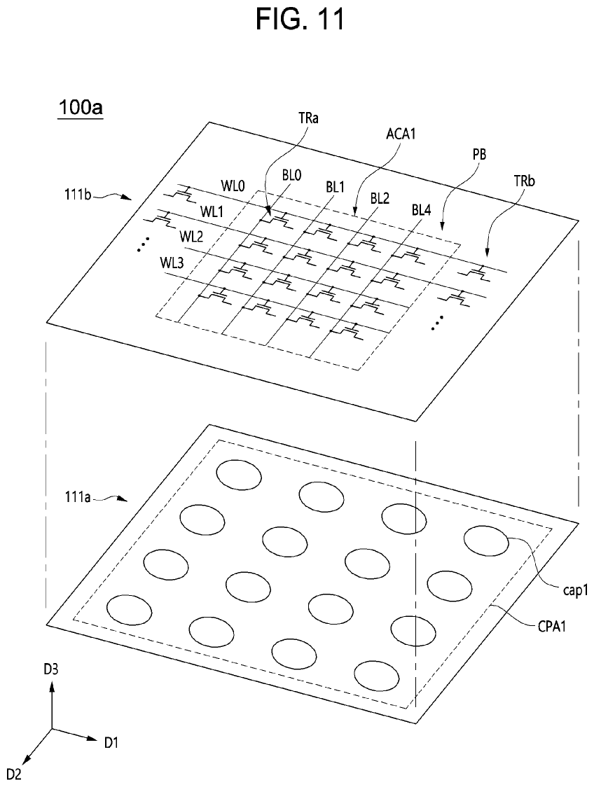

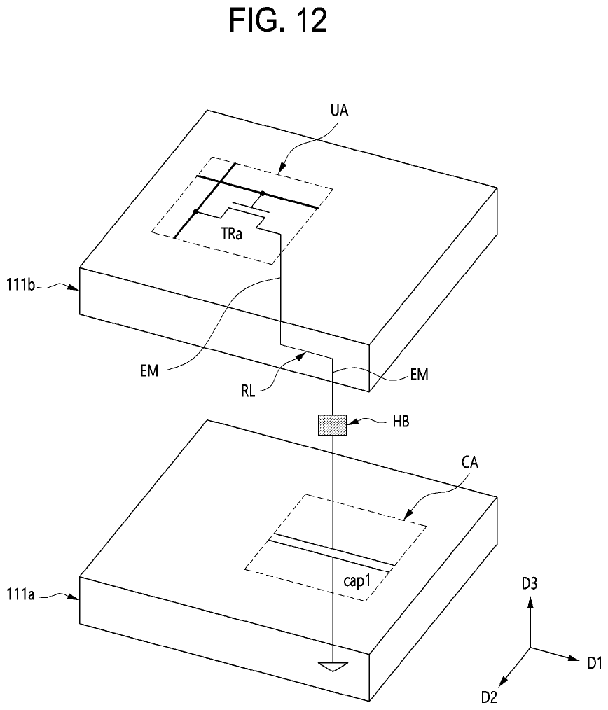

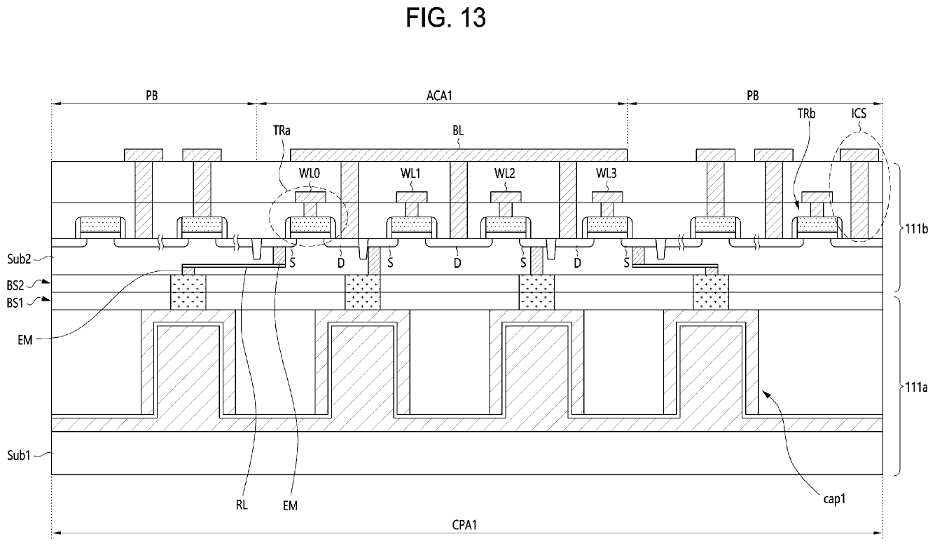

FIG. 11 is a perspective view illustrating a stack type semiconductor memory device in accordance with an embodiment of the disclosure, FIG. 12 is a perspective view illustrating a memory cell array of the stack type semiconductor memory device in FIG. 11 and FIG. 13 is a cross-sectional view illustrating the stack type semiconductor memory device in FIG. 11.

Referring to FIGS. 11 to 13, a stack type semiconductor memory device 100a of an embodiment of the disclosure may include a first structure 111a and a second structure 111b hybrid-bonded to the first structure 111a.

The first structure 111a may include a first substrate Sub1 on which a capacitor array CPA1 may be integrated. The capacitor array CPA1 may include a plurality of capacitors cap1. The first structure 111a may further include a first bonding layer BS1 on the capacitor array CPA1. The first bonding layer BS1 may include first bonding pads BP1 and a first bonding insulation layer Bl1. The first bonding pads BP1 may connect to the capacitors cap1, respectively. The first bonding insulation layer Bl1 may electrically isolate the first bonding pads BP1 from each other. For example, the first bonding pads BP1 may be positioned at a region corresponding to the capacitors cap1. The first bonding pads BP1 may electrically connect to the storage electrodes ST of the capacitors cap1.

The second structure 111b may include a second substrate Sub2. A second bonding layer BS2 may be formed on a lower surface of the second substrate Sub2. The second bonding layer BS2 may be bonded to the first bonding layer BS1. The second bonding layer BS2 may include second bonding pads BP2 and a second bonding insulation layer BI2. The second bonding pads BP2 may correspond to the first bonding pads BP1. The second bonding insulation layer BI2 may electrically isolate the second bonding pads BP2 from each other.

An access array ACA1 and a peripheral circuit block PB may be integrated on an upper surface of the second substrate Sub2. The access array ACA1 may include a plurality of access transistors TRa, a plurality of word lines WL0˜WL3 and a plurality of bit lines BL0˜BL3 similarly to the access array in FIG. 2. The peripheral circuit block PB may be arranged on an outer perimeter of the access array ACA1. The peripheral circuit block PB may include circuits in the peripheral circuit block 190 in FIG. 1. The peripheral circuit block PB may include a plurality of transistors TRb (hereinafter, referred to as peripheral transistors) and multi-layered interconnections ICS. The peripheral transistors TRb may form the memory control logic 105, the address register 120, the bank control logic 130, the row selection circuit 140, the column selection circuit 160, the sense amplification circuit 150, the input/output gating circuit 170 and the data input/output buffer 180.

In an embodiment of the disclosure, the access transistors TRa and the peripheral transistors TRb may be formed on a same surface of a same substrate by a same process. The access transistor TRa and the peripheral transistor TRb may have varied sizes, i.e., different channel lengths. Further, the peripheral transistors TRb may have various channel lengths suitable for characteristics of the circuits.

Although not illustrated in the drawings, a part of the peripheral transistors TRb may be directly and indirectly connected with the word lines WL0˜WL3 of the access array ACA1 through the interconnections ICS. Another part of the peripheral transistors TRb may directly and indirectly connect with the bit line BL of the access array ACA1 through the interconnections ICS.

In an embodiment of the disclosure, the capacitor array CPA1 may face the peripheral circuit block PB as well as the access array ACA1. An occupying area of the capacitors cap1 may be substantially larger than an area of a unit memory cell region UA causing the semiconductor memory device to have an increased capacitance.

For example, the capacitor cap1 of an embodiment of the disclosure may have a size larger than a size of the capacitor cap in FIG. 4. Because the first and second bonding pads BP1 and BP2 may be arranged corresponding to the capacitors cap1, the access transistors TRa, which may be integrated in a small area, may not face the second bonding pads BP2.

In this case, in order to electrically connect the second bonding pads BP2 with the access transistors TRa, particularly, the sources S of the access transistors Tra, at least one embedded electrode EM and at least one routing line RL may be formed in the second substrate sub2. Structures of the embedded electrode EM and the routing line RL may change a connection path between the second bonding pads BP2 and the access transistors TRa.

Further, although not illustrated in the drawings, when the second substrate sub2 may include a semiconductor material layer, and at least one insulation layer, the embedded electrode EM and the routing line RL may be formed between the semiconductor material layer and the insulation layer or between the insulation layers.

The access array ACA1 and the peripheral circuit block PB may be formed after forming the capacitors cap1 and hybrid-bonding the first bonding layer BS1 to the second bonding layer BS2 by a hybrid-bonding portion HB. Thus, the access transistors TRa, the wirings WL and BL and the interconnections (not shown) in the access array ACA1 and the peripheral circuit block PB may not be affected by the high temperature process and the thermal process for the hybrid-bonding. As a result, the transistors TRa and TRb, the wirings WL and BL and the interconnections ICS in the access array ACA1 and the peripheral circuit block PB may increase electrical reliability.

Further, the area CA of the capacitors cap1 may increase to secure the capacitance of the memory device.

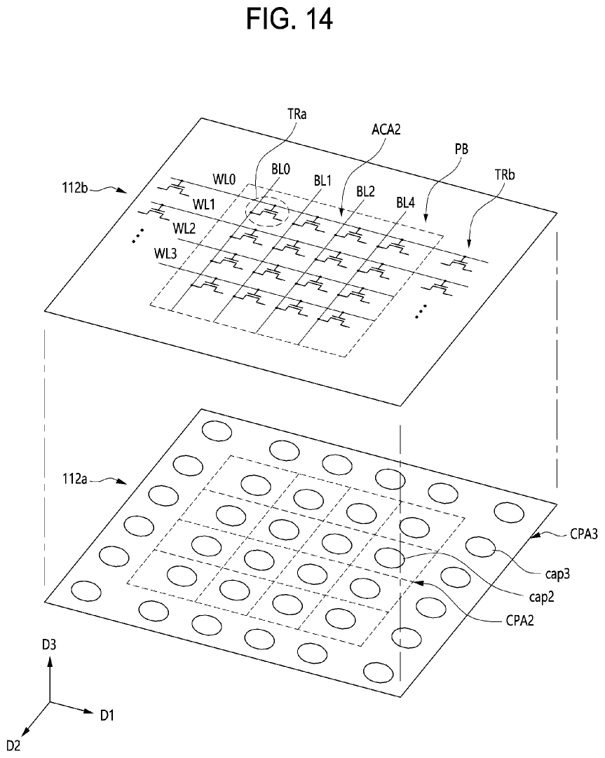

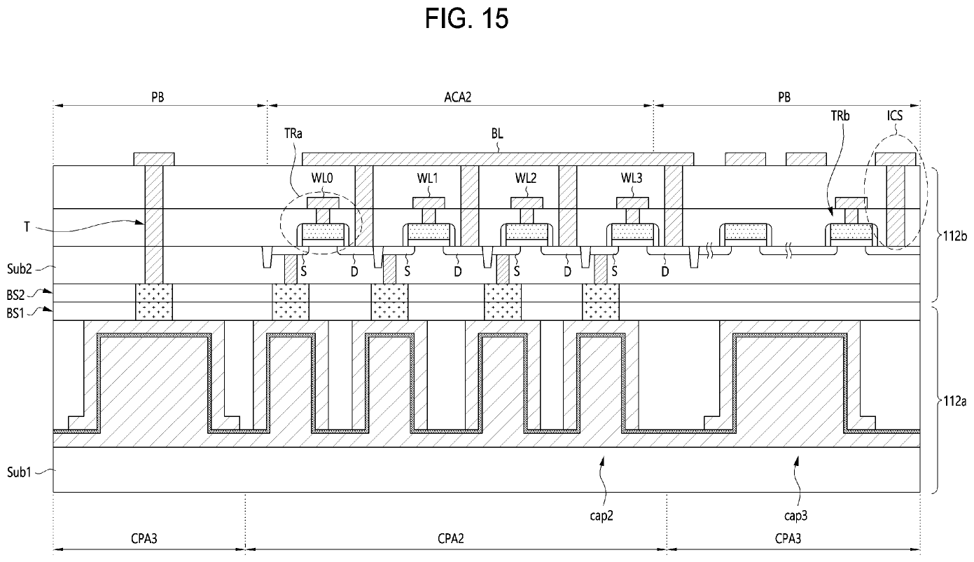

FIG. 14 is a perspective view illustrating a stack type semiconductor memory device in accordance with an embodiment of the disclosure and FIG. 15 is a cross-sectional view illustrating the stack type semiconductor memory device in FIG. 14.

Referring to FIGS. 14 and 15, a stack type semiconductor memory device 100b of an embodiment of the disclosure may include a first structure 112a and a second structure 112b hybrid-bonded to the first structure 112a.

The first structure 112a may include a first substrate Sub1. A first capacitor array CPA2 and a second capacitor array CPA3 may be integrated on the first substrate Sub1.

The first capacitor array CPA2 may include a plurality of cell capacitors cap2. As shown in FIG. 2, the cell capacitors cap2 may have a size corresponding to the size of a region where the memory cell may form, or the size of the unit memory cell region UA.

The second capacitor array CPA3 may be positioned on an outer perimeter of the first capacitor array CPA2. The second capacitor array CPA3 may include a plurality of micro capacitors cap3. The micro capacitors cap3 may have substantially the same size or different sizes. The micro capacitors cap3 may stabilize a power voltage. For example, the micro capacitors cap3 may have a size substantially equal to or different from the size of the cell capacitors cap2. Further, the size of the micro capacitors cap3 may change in accordance with integration positions and connected circuits.

In an embodiment of the disclosure, the cell capacitors cap2 and the micro capacitors cap3 may be formed on a same plane by a same process.

For example, each of the micro capacitors cap3 may have a capacitance substantially the same as a capacitance of each of the cell capacitors cap2. At least one of the micro capacitors cap3 may have a capacitance different from the capacitance of the cell capacitors cap2. Further, the micro capacitors cap3 may have capacitances different from the capacitance of the cell capacitors cap2. A part of the micro capacitors cap3 may have a capacitance substantially the same as the capacitance of the cell capacitors cap2 and the remaining micro capacitors cap3 may have a capacitance different from the capacitance of the cell capacitors cap2.

The first structure 112a may further include a first bonding layer BS1 on the first capacitor array CPA2 and the second capacitor array CPA3. For example, the first bonding layer BS1 may include a plurality of first bonding pads BP1 and a first bonding insulation layer Bl1. The first bonding insulation layer Bl1 may electrically isolate the first bonding pads BP1 from each other.

A part of the first bonding pads BP1 may be formed at a region corresponding to the cell capacitors cap2. The part of the first bonding pads BP1 may electrically connect to the storage electrodes ST of the cell capacitors cap2. Another part of the first bonding pads BP1 may electrically connect to the micro capacitors cap3.

The second structure 112b may include a second substrate sub2. A second bonding layer BS2 may be formed on a lower surface of the second substrate sub2. The second bonding layer BS2 may bond to the first bonding layer BS1 of the first structure 112a. The second bonding layer BS2 may include a plurality of second bonding pads BP2 and a second bonding insulation layer BI2. The second bonding pads BP2 may correspond to the first bonding pads BP1. The second bonding insulation layer BI2 may electrically isolate the second bonding pads BP2 from each other.

An access array ACA2 and a peripheral circuit block PB may be integrated on an upper surface of the second substrate sub2. The access array ACA2 may include a plurality of access transistors TRa, a plurality of word lines WL0˜WL3 and a plurality of bit lines BL0˜BL3 similarly to the access array ACA1 of FIG. 11. The peripheral circuit block PB may be arranged on an outer perimeter of the access array ACA2. The peripheral circuit block PB may have a configuration substantially the same as the configuration of the peripheral circuit block PB in FIG. 11.

In an embodiment of the disclosure, a region where the access array ACA2 and the access transistors TRa may face a region where the cell capacitors cap2. For example, the access transistors TRa may correspond to the cell capacitors cap2. Thus, the source S of the access transistors TRa may be electrically connected with a part of the second bonding pads BP2 facing the first bonding pads BP1 through an embedded electrode without a routing line. Further, another part of the second bonding pads BP2 may electrically connect with electrical components of the peripheral circuit block PB.

The peripheral circuit block PB may further include a penetration electrode T formed through the second structure 112b. The penetration electrode T may be electrically connected to the second bonding pad BP2. In an embodiment of the disclosure, the penetration electrode T may include a multi-layered wiring structure. The penetration electrode T may directly and indirectly connect with a circuit block configured to receive a power voltage. Thus, the penetration electrode T may electrically connect with the micro capacitors cap3 of the first structure 112a.

The access array ACA2 and the peripheral circuit block PB may be formed after forming the cell capacitors cap2 and the micro capacitors cap3 and hybrid-bonding the first bonding layer BS1 to the second bonding layer BS2. Thus, the access transistors TRa, the wirings WL and BL and the interconnections ICS in the access array ACA2 and the peripheral circuit block PB may not be affected by the high temperature process for forming the cell capacitors cap2 and the micro capacitors cap3 and the thermal process for the hybrid-bonding. As a result, the transistors TRa and TRb, the wirings WL and BL and the interconnections ICS in the access array ACA1 and the peripheral circuit block PB may have increased electrical reliability.

Further, the micro capacitors cap3 may be integrated on the first structure 112a together with the cell capacitors cap2 so that the power voltage may be stably provided to the access array ACA2 and the peripheral circuit block PB.

According to an embodiment of the disclosure, the capacitors formed by the high temperature process and the circuit elements such as the transistor formed by a non-high temperature process may be integrated on the different substrates. Thus, preventing electrical changes of the circuit elements caused by the high temperature process.

Further, the circuit elements such as the transistors formed by the non-high temperature process may be formed after the high temperature process for forming the capacitors and the hybrid-bonding process. Thus, thermal burdens, which may change the electrical characteristics of the circuit elements can decrease. As a result, the stack type semiconductor device may have improved electrical characteristic. Furthermore, the circuit elements and the capacitors may be formed on the different substrates to increase the degree of integration of a memory device.

In an embodiment of the disclosure, the two substrates or the two structures may be exemplarily illustrated, but not limited thereto.

The above described embodiments of the present disclosure are intended to illustrate and not to limit the present disclosure. Various alternatives and equivalents are possible. The disclosure is not limited by the embodiments described herein. Nor is the disclosure limited to any specific type of semiconductor device. Another additions, subtractions, or modifications in view of the present disclosure and are intended to fall within the scope of the appended claims.

What is claimed is:

1. A stack type semiconductor memory device comprising:
a first structure comprising: a first substrate, a capacitor array, and a first bonding layer, the first substrate having an upper surface and a lower surface, the capacitor array having a plurality of capacitors integrated on the upper surface of the first substrate, and the first bonding layer formed on the capacitor array; and
a second structure comprising: a second substrate, an access array, and a second bonding layer, the second substrate having an upper surface and a lower surface, the access array having a plurality of access transistors integrated on the upper surface of the second substrate, and the second bonding layer formed on the lower surface of the second substrate and bonded to the first bonding layer.

2. The stack type semiconductor memory device of claim 1, wherein the first bonding layer comprises:
a plurality of first bonding pads electrically connected to the capacitors, respectively; and
a first bonding insulation layer configured to electrically isolate the first bonding pads from each other.

3. The stack type semiconductor memory device of claim 2, wherein the second bonding layer comprises:
a plurality of second bonding pads hybrid-bonded to the first bonding pads and electrically connected to the access transistors, respectively; and
a second bonding insulation layer hybrid-bonded to the first bonding insulation layer and configured to electrically isolate the second bonding pads from each other.

4. The stack type semiconductor memory device of claim 3, wherein the capacitor array has a size corresponding to a size of the access array.

5. The stack type semiconductor memory device of claim 4, wherein the second structure further comprises an embedded electrode in the second substrate to connect the access transistors to the second bonding pads.

6. The stack type semiconductor memory device of claim 3, wherein the second structure further comprises:
a plurality of transistors arranged on an outer perimeter of the access array; and
a peripheral circuit block including a plurality of interconnections electrically connected to the transistors.

7. The stack type semiconductor memory device of claim 6, wherein the capacitor array has a size corresponding to sizes of the access array and the peripheral circuit block.

8. The stack type semiconductor memory device of claim 7, wherein the second structure further comprises:
a plurality of embedded electrodes in the second substrate to couple with the access transistors; and
a plurality of routing lines connected between the embedded electrodes and the second bonding pads.

9. The stack type semiconductor memory device of claim 6, wherein the first structure further comprises a plurality of micro capacitors,
wherein the plurality of micro capacitors is arranged to face the peripheral circuit block of the second structure.

10. The stack type semiconductor memory device of claim 9, wherein the plurality of micro capacitors is formed at a same plane as the capacitors, and a shape of the micro capacitors is equal to or different from the shape of the capacitors.

11. A stack type semiconductor memory device comprising:
a first substrate including a plurality of cell capacitors; and
a second substrate including a plurality of word lines, a plurality of bit lines intersected with the word lines, and access transistors connected to intersected portions between the word lines and the bit lines,
wherein at least one of the first substrate and the second substrate comprises a plurality of hybrid-bonding pads connected between the cell capacitors and the access transistors to form a memory cell array.

12. The stack type semiconductor memory device of claim 11,
wherein the second substrate comprises a peripheral circuit block including a plurality of transistors and a plurality of interconnections connected to the word lines and the bit lines,
wherein the peripheral circuit block is integrated on the second substrate where the access transistors, the word lines and the bit lines are integrated.

13. The stack type semiconductor memory device of claim 12, wherein the first substrate further comprises a plurality of micro capacitors arranged at a region corresponding to the peripheral circuit block.

14. The stack type semiconductor memory device of claim 13, further comprising:
a first bonding layer formed on the cell capacitors and the micro capacitors of the first substrate; and
a second bonding layer formed on the second substrate facing the first substrate to be bonded to the first bonding layer,
wherein the first bonding layer and the second bonding layer comprise the plurality of hybrid-bonding pads.

15. The stack type semiconductor memory device of claim 13, wherein each of the micro capacitors has a capacitance substantially equal to a capacitance of each of the cell capacitors.

16. The stack type semiconductor memory device of claim 13, wherein at least one of the micro capacitors has a capacitance different from a capacitance of the cell capacitors.
